(19) United States
(12) Patent Application Publication
(10) Pub. No.: US 2005/0083989 A1
(43) Pub. Date: Apr. 21, 2005

(54) Process and apparatus for melting inorganic substances

(75) Inventors: Michael Leister, Budenheim (DE); Volker Ohmstede, Mainz (DE); Andreas Grobeta, Gustavsburg (DE); Ernst-Walter Schafer, Welgesheim (DE); Guido Rake, Pfaffen-Schwabenheim (DE); Hildegard Romer, Karben (DE)

Correspondence Address: Charles N. J. Ruggiero, Esq.;Ohlandt, Greeley, Ruggiero & Perle, L.L.P., 10th Floor, One Landmark Square, Stamford, CT, 06901-2682, US

(73) Assignee: Schott Glas

(21) Appl. No.: 10/882,515

(22) Filed: Jul. 1, 2004

(30) Foreign Application Priority Data
Jul. 2, 2003 (DE) 103 29 718.9

(51) Int. Cl. C03B 5/02; C30B 15/00; C30B 21/06; C30B 27/02; C30B 28/10; C30B 30/04; C03B 37/01

(52) U.S. Cl. 373/27; 65/441

(57) ABSTRACT

In order, inter alia, to provide an apparatus and a process for melting inorganic substances which allow a high product quality to be obtained and the technological outlay to be reduced, the invention provides a process and an apparatus in which the volumetric ratios between a melting region and a refining region can be flexibly adapted. The process comprises the steps of adding a batch into at least one first region (12) on the feed side (10) of a scull crucible (1), heating the crucible contents (30), melting down the crucible contents (30) in the at least one first region (12) of the scull crucible (1), entry into at least one second region (22) on the discharge side (20) of the scull crucible (1), melting down and/or refining the crucible contents (30) in the at least one second region (22) of the scull crucible (1), and removing the melted-down crucible contents through at least one removal apparatus (25), with the volume on the feed side (10) and/or the discharge side (20) of the scull crucible (1) being set variably.

The invention relates to a process and an apparatus for melting inorganic substances in general and glasses in particular in a scull crucible in accordance with the preambles of claims 1 and 25.

Scull crucibles are constructed from coolant-cooled, slotted metal tubes. The introduction of radiofrequency energy allows inorganic substances, in particular glasses, to be heated and melted in a scull crucible.

Corrosive glasses requiring high purity levels are nowadays melted continuously in cooled tank furnaces made from refractory material or scull tanks. In the case of the refractory tank furnaces, the melting tank consists of ceramic materials, and the refining and homogenization unit usually consists of platinum. This melting technology is disadvantageous on account of the high costs of the precious metal and also the short service lives of the refractory tank furnaces.

Scull units for melting or refining have the advantage over the melting tanks referred to above that the corrosive glass melt forms a protective layer of material of the same type as the glass batch as a result of the cooling in the edge region of the melting tank.

In general, these radiofrequency-heated scull units are used in melting installations. A melting installation of this type is described in German patent application 102 44 807.8, in the name of the present Applicant. Like the refractory tank furnaces, radiofrequency-heated scull units are usually also connected in series with a platinum refining and homogenization unit. On account of the use of the scull unit, only the melting region, in which the batch reactions take place and which is exposed to considerable corrosion, has significantly longer service lives. Overall, however, a platinum system of this type, like a refractory tank furnace, has the drawbacks of high costs and short service lives.

Patent EP 0 176 898 describes a corresponding melting installation operated with an induction coil. It is arranged vertically and operates using what is known as the cold top process, i.e. the batch is laid onto the cold surface of the installation and melted down in a lower-lying part of the installation and then refined. The refining zone is adjoined by an unheated calming zone, which is no longer surrounded by the induction coil. The glass is then fed for hot shaping.

On account of the vertical mode of operation and the absence of any separation between the melting-down part and the refining part of the installation, however, there are serious drawbacks with regard to homogeneity and the absence of residues in the melt. Consequently, either only a poor quality of product or a low throughput can be achieved.

To melt glasses with high demands imposed on the purity, it is possible for the radiofrequency-heated melting unit also to be combined with a scull refining unit which is likewise heated by radiofrequency. In this case, it is possible to achieve an optimum glass quality in terms of the internal quality by producing a high transmission and a low number of bubbles and other inclusions. A corresponding radiofrequency refining trough is described in German patents 199 39 782.1 and 199 39 784.8 and 199 39 786.4, in the name of the present Applicant. A radiofrequency refining vessel is given by German patents 199 39 779.1 and 199 399 772.4, in the name of the present Applicant.

Parallel operation of two radiofrequency units operated independently of one another but spatially very close together, however, gives rise to the drawback of immense technological outlay. If the glasses are only intended to form an intermediate product which is processed further, moreover, it is not necessary to optimize all the relevant parameters relating to the internal quality. For example, in the case of glass rods used to produce optical fibers, in particular a few bubbles can be accepted.

However, the known installations described cannot be flexibly adapted to changing demands on the product quality. Consequently, the overall mode of operation is uneconomical.

The drawbacks which arise from the need for parallel operation of two radiofrequency units working independently of one another are also encountered with the arrangements described by patents DE 147 1907 and JP-57-95834.

DE 147 1907 describes a unit which is designed as a vertically arranged zone-melting process with two induction coils arranged one behind the other. The induction coils are moved over the material to be melted from the bottom upward. A melting-down region can form in the field of the first coil, and a refining region can form in the field of the second coil.

However, the refining bubbles which are formed in the refining region have to rise up through the first region and the cold top layer above it. The vertical arrangement lengthens this path which has to be covered by the refining bubbles, increasing the time required for the refining. Moreover, there is no heatable, exposed melt surface.

The second document mentioned, JP-57-95834, describes a melting tank furnace which may be arranged vertically or horizontally as desired. The melting region and the refining region are separated to different extents in different embodiments.

However, the volumetric ratio of melting region to refining region is unfavorable in every embodiment. Irrespective of the separation between the volumes for the melting region and the refining region, at least two induction coils and the associated radiofrequency generators are always required. This installation therefore resembles the radiofrequency refining trough described above and the radiofrequency refining pot described above. Operation of installations of this type is correspondingly complex and expensive.

In addition to the arrangement of the melting region and of the refining region of a melting installation, the way in which the melt is removed also plays an important role with regard to the product quality and the economic operation of the overall installation.

In continuously operating radiofrequency melting installations, the melt is usually removed via a cooled scull overflow directly above the radiofrequency coil. The scull overflow comprises angled-off tubes and projects beyond the induction coil.

Quasi-continuous removal of the melt is described, for example, in the article “Continuous casting glass melting in a cold crucible induction furnace” by Yu. B. Petrov et al. in Proceedings Vol. 3a, IV. International Congress on Glass, 1989, pp. 72-77.

A further arrangement is described in German patent 101 48 754.1, in the name of the present Applicant. This arrangement has already been able to make advances compared to the previously proposed quasi-continuous removal of the melt by the melt dropping freely through between the scull crucible and radiofrequency coil.

Nevertheless, the process still has serious drawbacks. By way of example, the melt can no longer be heated by the introduction of radiofrequency energy over the entire overflow region and removal region on the removal side, since the volume of melt in this region is too small and, moreover, is located too far above the radiofrequency coil. In addition, the cooling area of the scull wall which adjoins the melt during removal is relatively large, resulting in correspondingly high removal of heat from the melt. Therefore, there is a very high risk of thermal cords forming in the glass in particular in the overflow region of the melt. Moreover, the uncontrolled temperature management means that the glass can easily crystallize, even to the extent of the melt flow freezing.

To avoid this, it is usually possible to use a burner which generates additional top heat. However, further drawbacks are associated with this solution. Burners cause increased evaporation of highly volatile glass components. This changes the composition of the glass at the exit from the melting unit.

Furthermore, the use of a burner produces an extreme temperature gradient as a result of strong heating of the surface combined, at the same time, with cooling of the underside of the overflowing glass flow. This further leads to extensive formation of thermal cords. Moreover, there is a risk of electrical sparkovers between the tubes of the scull crucible and the overflowing glass strand.

Therefore, the circumstances described above give rise to an object of the invention of providing an apparatus and a process for melting inorganic substances in general and glasses in particular which allow a high product quality to be obtained. In particular, it is an object of the invention to allow a melt with the minimum possible number of residues to be produced. A further object of the invention is to allow reliable and permanent setting of the glass composition to be realized and to allow thermal cords to be eliminated.

Moreover, it is an object of the invention to reduce the technological outlay involved in the melting compared to the prior art. In particular, it is intended for it to be possible to flexibly adapt the volumetric ratios between a melting region and a refining region. A further object of the invention is to eliminate sources of danger. Electrical sparkovers, in particular during removal, and freezing of the melt flow in particular during removal, are to be avoided.

Moreover, it is an object of the invention to provide an inexpensive solution by minimizing the technological outlay, in particular by reducing the number of coils with associated radiofrequency generators.

These objects are achieved in an amazingly simple way just by the features of claim 1. Furthermore, claim 25 gives an apparatus in which the process can be used. Advantageous refinements of the invention are to be found in the associated subclaims.

The invention therefore for the first time provides a process for melting inorganic substances, in particular glasses, in a scull crucible, the scull crucible having a feed side and a discharge side, and the process comprising the steps of adding a batch into at least one first region of the feed side of the scull crucible, heating the crucible contents, melting down the crucible contents in the at least one first region of the scull crucible, entry of the crucible contents into at least one second region of the discharge side of the scull crucible, melting down and/or refining the crucible contents in the at least one second region of the scull crucible, and removing the melted-down crucible contents through at least one removal apparatus, wherein the volume of the feed side and/or the discharge side of the scull crucible can be set variably.

The variable setting of the volume on the feed side and/or the discharge side of the scull crucible allows the solution of the invention to offer the major advantage of significantly reducing the technological outlay by making it possible to flexibly adapt the volumetric ratio on the two sides. This makes it possible to realize a high product quality for a very wide range of compositions of the inorganic substance, in particular of a glass, since it is possible in particular to ensure that there are no residues left in the melt.

The feed side of the scull crucible comprises a region where the batch is added and a first region which forms the melting tank with respect to conventional processes. The discharge side of the scull crucible comprises a second region, which represents the refining tank with respect to the known processes, and a removal region.

The change in the volume on the feed side and/or the discharge side can be realized by changing the spatial ratio between the two sides and/or by using variably positionable internal fittings on one side.

The invention provides in particular for the volume on the feed side and/or the discharge side to be set by variable positioning of at least one bridge. The melt to be refined can flow through under the bridge from the first region on the feed side, ensuring that no batch residues are drawn off with it. After it has flowed under the bridge, the melt which is to be refined passes into the second region on the discharge side, where the melt can be refined. Therefore, depending on the throughput and demands imposed on the product quality, it is possible to produce virtually bubble-free and residue-free melts and for these melts then to be fed for further processing.

The position of the bridge can advantageously be varied in accordance with the invention. For example, a horizontal movement of the bridge allows the ratio of the volume of the melting region to that of the refining region to be set as a function of the type of glass to be melted, the throughput to be achieved and the demands imposed on glass quality. Vertical adjustment of the bridge allows the geometry of the connection between the first region on the feed side and the second region on the discharge side to be set. This allows flowback to be permitted or suppressed, and also allows deliberate flow paths to be opened up or closed or imposed.

As a result of the variable positioning of the at least one bridge, the invention offers the advantage of allowing the flow of the crucible contents to be set. In this context, it is possible to set the flow of the crucible contents in the first region and/or the flow of the crucible contents from the first region into the second region and/or the flow of the crucible contents in the second region and/or the flow of the crucible contents from the second region into the removal apparatus. For this purpose, the bridge is positioned horizontally and/or vertically.

In the simplest case, the position of the at least one bridge can be set while the installation is being started up. For this purpose, a position for the bridge is defined according to the demands imposed on the process, in particular the throughput and the temperature of the melt which can be reached, and as a function of the desired product quality. In this way, the invention uses a very simple principle to offer the advantage of flexible adjustment to different operating procedures and products.

In order, furthermore, to allow the installation to be adapted during operation to the parameters changing during the process, in particular the temperature of the melt and therefore its viscosity, the invention advantageously also offers the option of altering the position of the at least one bridge while the process is being carried out.

To allow particularly accurate adjustment to the changing materials parameters and if appropriate to allow the process to be optimized in the event of operating parameters changing, furthermore, the invention allows the position of the at least one bridge to be controlled while the process is being carried out.

Significantly improved adapting of the procedure to changing parameters is achieved, in a surprisingly simple way, purely by the position of the at least one bridge being set as a function of the viscosity of the crucible contents. The viscosity of the crucible contents is a decisive factor in determining the flow properties thereof. Therefore, the flow in the scull crucible divided by the bridge is influenced by the viscosity of the crucible contents. The viscosity is in particular a function of the temperature.

Particularly when the installation is being started up or in the event of fluctuations, for example in the event of fluctuations when the batch is being added, the temperature and therefore the viscosity of the crucible contents may change, so that the flow through the scull crucible divided by the bridge changes. On the one hand, this may cause a departure from the form of flow which is most favorable for the process to be carried out efficiently. On the other hand, undesirable dead zones may form.

Responsive control in accordance with the invention offers the major advantage of adapting the position of the bridge to the changed conditions and therefore ensuring constant flow management even in the event of changing values for the abovementioned parameters.

To counteract the thermal attack of the melt on the bridge, the invention advantageously provides for the at least one bridge to be cooled.

Surprisingly, it has been found that the introduction of cold batch on the feed side and the overflow of melt which is already hot into the second region on the discharge side results in the formation of a temperature difference between the first region on the feed side and the second region on the discharge side which can be used to refine the unrefined melt.

Suitable selection of the position of the at least one bridge allows this effect to be reinforced or weakened depending on the throughput. In this way, the invention makes it possible to realize a relatively wide range for the temperature difference between the first region on the feed side and the second region on the discharge side. The invention therefore provides for a temperature difference between the contents of the first region on the feed side and the contents of the second region on the discharge side to be set by variable positioning of the at least one bridge.

In addition to the variable positioning of at least one bridge as described above, the invention furthermore offers a further option of variably setting the volume on the discharge side of the scull crucible by variably positioning at least one removal apparatus.

This removal apparatus may, for example, be a tube whose external diameter, penetration depth and arrangement in the second region on the discharge side influence its volume. The variable positioning of the at least one removal apparatus advantageously allows the invention to match the volumetric ratios of feed side and discharge side to a very wide range of demands.

Furthermore, the possibility of adapting the process to operation with downstream process steps, in particular of homogenization and/or shaping, with extremely little technological outlay is opened up in a surprisingly simple way by simply selecting the position of removal in such a way that the path to the next unit can be covered optimally.

The removal of the melt in the process according to the invention can take place at virtually any desired locations in the scull crucible above, within or below the radiofrequency coil or even at the bottom of the crucible. By adapting the radiofrequency coil and correctly arranging the removal apparatus, it is possible to virtually eliminate the risk of electrical sparkovers between the scull crucible and the melt to be removed in a surprisingly simple way.

Furthermore, the invention provides for a second step of heating the melted-down and/or refined crucible contents to be performed, this step being carried out during the removal. Thus, the melt can be held at the desired temperature during removal, irrespective of the introduction of the radiofrequency energy which heats the scull crucible itself. This ensures precise temperature control in the melting installation as a whole from introduction all the way through to post-processing.

For the second heating step, the invention advantageously provides the simple option of carrying out direct electrical heating. The heating prevents excessive cooling of the melt during removal, so that the risk of thermal cords being formed is advantageously reduced.

In order also to reduce the risk of excessive heating of the melt during removal, the invention provides a step of cooling the melted-down and/or refined crucible contents which is carried out during the removal.

The optimum temperature control of the melt during removal prevents extreme temperature gradients in the melt during removal and therefore virtually completely eliminates the formation of thermal cords. Therefore, the invention offers major advantages with regard to achieving a high product quality.

In order to provide a flexible solution with regard to demands and conditions for operation, the invention moreover provides for gas cooling, in particular air cooling and/or aerosol cooling, with the aerosol comprising in particular a water-air mixture, and/or liquid cooling, in particular water cooling, to be used to cool the melted-down and/or refined crucible contents during removal. Depending on the desired temperature curve, it is possible for the cooling to be carried out in co-current or in countercurrent to the melt during removal.

The combination of the variable positioning of at least one bridge and the variable positioning of at least one removal apparatus allows the invention to offer the major advantage of matching the volumetric ratios of feed side and discharge side of the scull crucible to one another in an extremely flexible yet simple way using two independent positioning operations.

For the step of heating the crucible contents, the invention provides for radiofrequency heating. To protect the scull crucible from thermal attack, it is cooled in accordance with the invention. To increase the melting capacity and/or the refining action, it is possible to increase the temperature of the crucible contents to virtually any desired extent, since according to the invention there are no wall contact materials of the scull crucible to constitute restricting variables.

To increase the melting capacity in a simple way, the invention offers the option of imparting forced convection to the flow of the crucible contents on the feed side and/or the discharge side. This can be generated in a simple way by stirring or bubbling.

Bubbling in particular on the discharge side of the scull crucible moreover assists with the upward movement of the refining bubbles and cools the melt even before it is removed. This allows the cooling capacity on the removal side to be reduced, with corresponding savings in the operating costs.

Furthermore the invention provides for a third step of heating the crucible contents. This advantageously opens up the option of temporally and/or locally increasing the introduction of heat into the crucible contents independently of the abovementioned heating of the scull crucible, in particular by means of radiofrequency energy.

The third step of heating the crucible contents may, according to the invention, comprise surface heating, which is carried out in particular on the feed side and/or on the discharge side. Heating of this nature, by way of example, makes it possible to advantageously assist the process of starting up the installation. While the installation is operating, moreover, heating of this nature can be used in a simple and variable way to increase the melting-down capacity and/or to control the temperature.

The process of the invention described above may advantageously be part of a production line. For this purpose, the invention provides for a further step of feeding the melted-down crucible contents for shaping to be carried out.

To allow a high product quality to be achieved at little technological outlay and favorable costs, the invention, in addition to the process, also relates to an apparatus for melting inorganic substances, in particular glasses, having a scull crucible which has a feed side with at least one first region and a discharge side with at least one second region. The scull crucible of the apparatus according to the invention also comprises a device for adding a batch into the at least one first region of the scull crucible, a device for heating the crucible contents and a removal apparatus, the apparatus according to the invention having at least one device for variably setting the volume on the feed side and/or the discharge side of the scull crucible.

If the at least one device for variably setting the volume on the feed side and/or the discharge side of the scull crucible is designed as a variably positionable bridge, the invention offers the advantage of a particularly simple and flexible arrangement.

According to the invention, any desired, flexible shaping of the scull crucible and/or the at least one variably positionable bridge is advantageously achieved by virtue of the fact that the scull crucible and/or the bridge comprises a metal, in particular special steel and/or platinum and/or copper and/or aluminum and/or alloys thereof.

Furthermore, the invention provides for the bridge to be slotted. This ensures that the radiofrequency energy which is introduced in order to heat the crucible contents is affected to the minimum possible extent. Therefore, the invention offers the advantage of ensuring a substantially homogenous distribution of the introduction of energy in the crucible contents despite the addition of an obstacle in the form of the bridge.

To protect the components of the apparatus from corrosion, the invention offers the amazingly simple option of the scull crucible and/or the at least one variably positionable bridge having a coating, in particular of plastic.

To allow the variably positionable bridge according to the invention to be arranged in any desired way, the apparatus according to the invention includes a device for the horizontal and/or vertical positioning of the at least one bridge. Moreover, the apparatus may be equipped with a device for changing the position of the at least one bridge while the process is being carried out. Furthermore, the invention provides for the apparatus to have a device for controlling the position of the at least one bridge while the process is being carried out.

To enable the bridge to be protected from thermal attack, the apparatus according to the invention is advantageously equipped with a device for cooling the at least one bridge.

The inventive solution to the above objects by providing a device for variably setting the volume on the discharge side of the scull crucible can also be realized in a likewise surprisingly simple way by means of a device other than a bridge. In this respect, the invention advantageously offers the option of the apparatus having at least one variably positionable removal apparatus for setting the volume on the discharge side. By way of example, by selecting the material, it is possible to adapt the variably positionable removal apparatus to a very wide range of demands, in particular with regard to the strength and thermal stability and also the production processes to be used. For this purpose, there is provision for the at least one variably positionable removal apparatus to comprise metal and/or ceramic and/or glass.

Furthermore, the apparatus according to the invention has a device for heating the at least one variably positionable removal apparatus. As a result, the apparatus according to the invention offers the option of influencing the temperature of the melt during removal from the heated scull crucible in a simple way. Thus, the temperature of the melt during removal can be set independently of the heating of the scull crucible itself.

The heating of the at least one variably positionable removal apparatus advantageously allows the invention to provide the possibility of reliably and permanently setting the glass composition by avoiding in particular a change to the composition caused by evaporation of constituents.

In addition to the heating, targeted setting of the temperature management can also be effected by cooling the removal apparatus, so that it is possible to avoid the conditions which lead to the formation of thermal cords. The temperature management which is realized in accordance with the invention moreover advantageously prevents the flow of melt from freezing during removal.

By way of example, in the case of soldering glasses the demands imposed on the internal quality, i.e. on the transmission and on the level of bubbles or cords, are not particularly high. In this case, a simple, single-walled, heatable platinum tube of suitable diameter can be used for the removal. A tube of this type can be introduced into the scull crucible through a removal opening. The removal opening may be arranged in the side wall of the scull crucible. Furthermore, removal through a scull opening arranged in the tank base with the aid of a single-walled, heatable platinum tube projecting into it is also possible.

In the case of high-quality optical glasses, significantly higher demands are imposed on the internal quality. To avoid the risk of regions of the heatable removal apparatus which are arranged in the vicinity of the device for heating the scull crucible itself overheating, it is possible for the variably positionable removal apparatus to be of double-walled design.

Therefore, the invention offers the major advantage of allowing the radiofrequency radiation of the scull crucible heating to be shielded at the outer tube. The inner tube is isolated and thermally decoupled from the outer tube by a layer of, for example, air or ceramic between the inner tube and the outer tube of the double-walled removal apparatus. For example, the inner tube can be heated by direct electrical heating with current independently of the introduction of radiofrequency for heating the contents of the scull crucible and held at the respectively desired temperature.

Extremely high demands are imposed on the transmission properties of fiber optic glasses, in particular glasses with a high UV transmission. It is in this case necessary in particular to minimize the introduction of precious metals into the melt as far as possible. This allows the level of precious metal ions and/or precious metal particles in the glasses, which can lead to a deterioration in the transmission properties, in particular in the short-wave (ultraviolet and blue) spectral region and to yellow discoloration of the glasses, to be lowered.

According to the invention, these problems can be counteracted in a particularly simple way by the variably possitionable removal apparatus not only being heatable but also being configured so as to be coolable. In this way, it is advantageously possible to lower the temperature in the region of contact between melt and precious metal to below critical temperature values for removal of the metal.

Accordingly, the apparatus according to the invention has a device for cooling the at least one variably positionable removal apparatus. This cooling device may include one or more cooling zones.

To prevent electrical sparkovers between the removal apparatus and the scull crucible and therefore to avoid damage to the apparatus, the apparatus according to the invention advantageously includes a device for short-circuiting the removal apparatus with the scull crucible.

To allow the apparatus of the invention for melting inorganic substances, in particular glasses, to be configured flexibly, by virtue of providing the option of setting the volumetric ratio between feed side and discharge side by means of at least two independent devices, the invention furthermore provides for an apparatus, in addition to a flexibly positionable bridge, also to have a variably positionable removal apparatus.

Moreover, the inventive configuration of the apparatus offers the option of the device for heating the crucible contents having a radiofrequency coil which at least partially surrounds the scull crucible in the vertical direction. Therefore, according to the invention, the entire crucible contents can be heated with just a single coil.

To enable the energy emitted by the radiofrequency coil to be introduced as efficiently as possible into the crucible contents, the apparatus according to the invention has a slotted scull crucible.

To advantageously prevent electrical sparkovers at the scull crucible and/or between the bridge and the scull crucible or the removal apparatus and the scull crucible, the invention offers the option of the apparatus having a device for short-circuiting the tubes which form the scull crucible. Accordingly, it is possible to provide a device for short-circuiting the bridge with the scull crucible, and a device for short-circuiting the removal apparatus with the scull crucible.

To prevent thermal attack on the scull crucible, the apparatus according to the invention has a device for cooling the scull crucible which in particular comprises cooling fingers, in particular bent cooling fingers.

The scull crucible is composed of individual tubes through which a cooling medium flows. The coolant may in particular take a meandering route. In this case, depending on the size of the scull crucible, it may be necessary to divide the crucible into individual segments, in each case if appropriate with a plurality of coolant circuits.

The tubes are kept slotted, and not electrically connected to one another, in the base region of the scull crucible in the case of relatively small crucibles with a volume of usually up to approximately 200 liters. In order in this case to prevent an electrical sparkover, by way of example mica platelets are positioned between the tubes.

By contrast, in the case of tanks with very large melt volumes, it may be expedient for an electrical short circuit of the tubes also to be provided in the base region of the scull crucible. At the upper end of the tube, all the tubes can be electrically short-circuited with one another. The coolant-cooled tubes are short-circuited with one another in the form of a ring around the outlet passages for the melt and are electrically connected to the removal apparatus for potential compensation.

In the case of relatively small tanks, the base region of the scull crucible is electrically insulated from the side walls of the scull crucible. This can be achieved in particular by the provision of a ceramic insulation layer, preferably mica. It is also possible for other materials which are not electrically conductive to be used in a corresponding way.

In the case of relatively large scull crucibles with a base short circuit of the side scull walls, the base plate may be in electrical contact with the walls. The base plate itself may, for example, comprise meandering tubes or be composed of segments arranged in the form of slices of cake.

In order to advantageously enable the melting capacity to be increased, the apparatus according to the invention offers the particularly simple option of using a device for stirring the crucible contents to impose a forced convection on the feed side and/or the discharge side of the scull crucible. This may furthermore also be realized by a device for introducing bubbles into the crucible contents (bubbling) on the feed side and/or the discharge side.

In particular in the case of high-viscosity melts, a stirring motion produced by bubbling or a stirrer has beneficial effects on the melting capacity. Bubbling in the refining region just in front of the removal tube moreover boosts the upward movement of the refining bubbles and cools the melt even before it is removed. Bubbling of this nature can be effected in the scull crucible either by a bubbling tube which is introduced from above or by a nozzle positioned in the base.

A further increase in the melting capacity can be achieved by the use of additional top heat, in particular in the region where the batch is added. Therefore, the apparatus according to the invention provides at least one third device for heating the crucible contents, which is arranged in particular on the feed side and/or on the discharge side and which in particular comprises at least one burner. As an alternative to the burner, it is also possible to provide direct or indirect electrical heating.

If a burner is used to generate the top heat, it may be helpful to design the scull crucible as what is known as a mushroom scull, in order to prevent burner-off gases from condensing on the cold components of the furnace top space. A mushroom scull of this type is described in German patent 199 39 772.4, the content of disclosure of which is hereby incorporated in its entirety by reference in the present application.

To enable the apparatus according to the invention to be advantageously linked into a production line, the apparatus has devices for further processing of the crucible contents. For example, the apparatus may comprise a device for homogenizing the melted-down crucible contents, which may in particular be connected downstream of the scull crucible. Furthermore, the apparatus may include a device for passing on the melted-down crucible contents.

The invention is described below on the basis of exemplary embodiments and with reference to the appended drawings. Identical components are denoted by identical reference numerals throughout the drawings, in which:

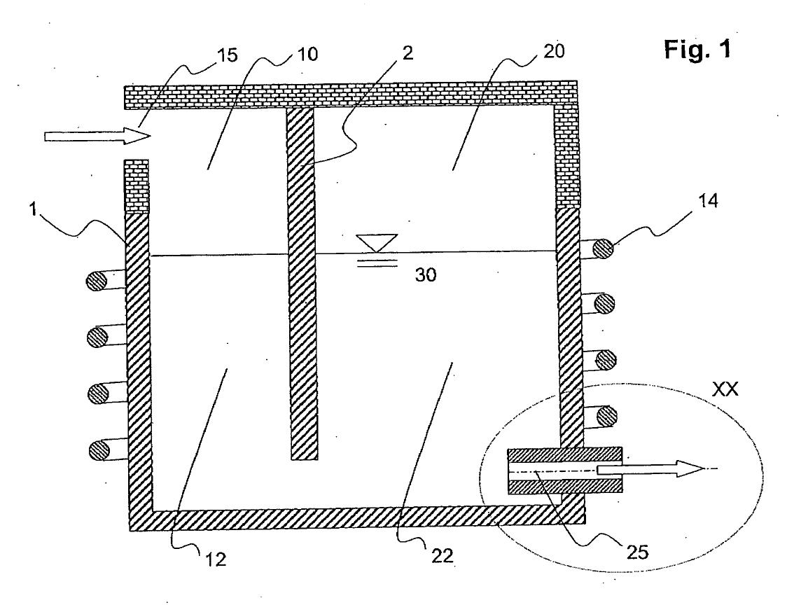

FIG. 1 diagramma tically depicts the basic structure of the apparatus according to the invention,

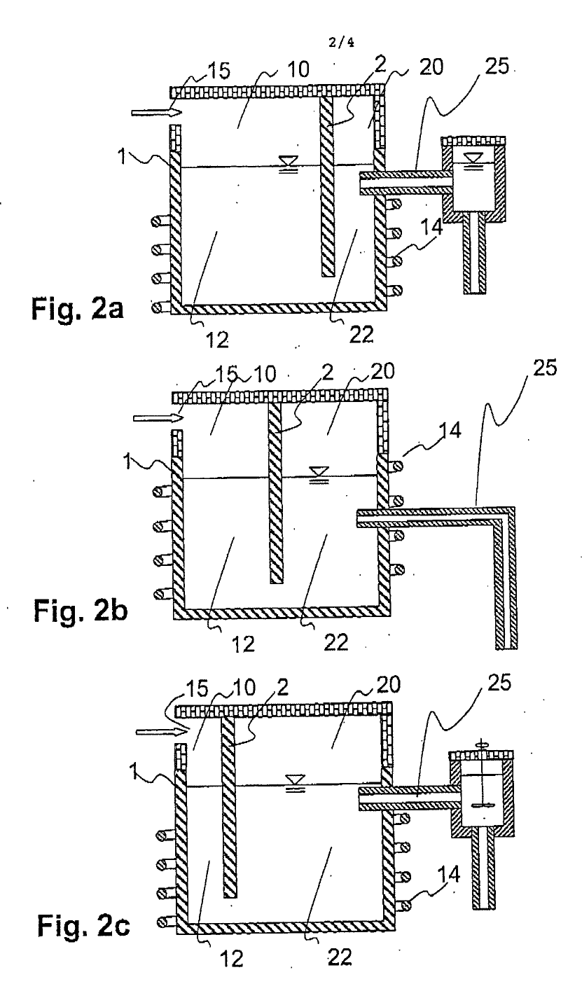

FIG. 2a diagramma tically depicts a first embodiment of the apparatus according to the invention for melting down glasses when there are low demands on the internal homogeneity,

FIG. 2b diagramma tically depicts a second embodiment of the apparatus according to the invention for use in melting-down glasses where there are high demands on the internal homogeneity and extremely high demands on the transmission, but low demands on the absence of bubbles,

FIG. 2c diagramma tically depicts a third embodiment of the apparatus according to the invention for melting down glasses with high demands on the internal homogeneity and transmission and on the absence of bubbles,

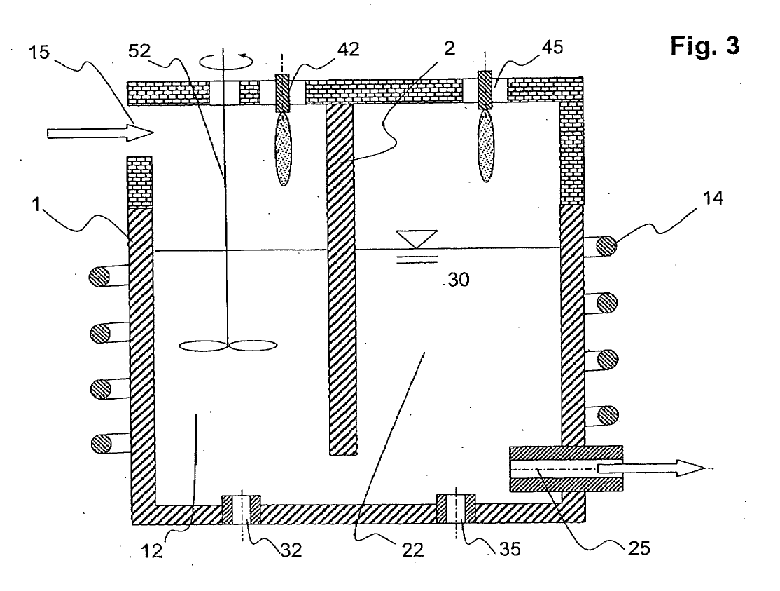

FIG. 3 diagramma tically depicts the apparatus according to the invention with additional devices for treating the crucible contents,

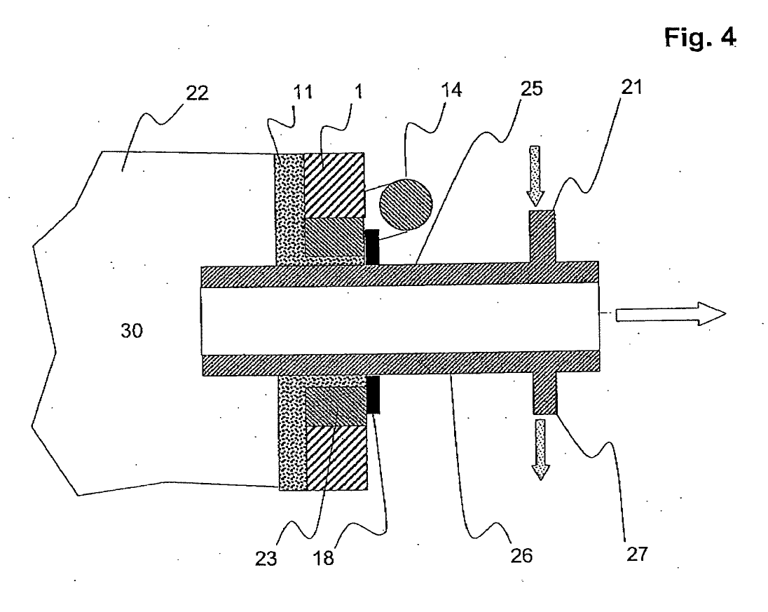

FIG. 4 diagramma tically depicts an enlarged excerpt XX from FIG. 1, showing a possible embodiment of the removal apparatus.

Reference will be made first of all to FIG. 1, which illustrates the apparatus according to the invention having a scull crucible 1, into which a batch is added through an opening 15. The scull crucible 1 comprises a feed region 10, which in addition to the opening 15 for adding the batch also comprises a first region 12 of the scull crucible. The feed region 10 is separated from the discharge region 20 by a variably positionable bridge 2. The discharge region 20 comprises a second region 22 and a removal apparatus 25. A coil 14 is illustrated in FIG. 1 as a device for heating the contents 30 of the scull crucible. On account of the heating of the crucible contents 30, the batch which has been added is melted down and can then be discharged via the removal apparatus 25.

The position of the bridge 2 is variable. For example, the ratio of the volumes of the first region 12 to the second region 22 can be set as a function of the type of glass to be melted, the throughput to be achieved and the glass quality, by means of a horizontal movement of the bridge. In this case, the melting of the batch which has been added substantially takes place in the first region 12, while the batch which has already been melted down is refined in the second region 22.

In the case of glasses with low demands on the internal homogeneity and absence of bubbles, the refining volume can be reduced in favor of the melting-down volume. A situation of this nature is illustrated in FIG. 2a. The variable bridge 2 is positioned in such a manner that the volume of the first region 12 is considerably larger than the volume of the second region 22 while retaining the same total volume, which is predetermined by the dimensions of the scull crucible. In this way, it is possible to achieve a maximum melting-down capacity of the installation.

Moreover, FIG. 2a shows a first possible embodiment of the removal apparatus 25. The melted-down and refined crucible contents 30 pass via an outlet tube 25, arranged above the radiofrequency coil 14, into a buffer vessel before being fed for further processing via a vertical tube.

The arrangement of the removal apparatus 25 is in this case variable, for example in FIG. 1 the removal apparatus 25 is arranged below the radiofrequency coil 14. To make the installation more compact, it is possible for the horizontal tube of the removal apparatus 25 to be shifted into the scull crucible 1. This too reduces the volume of the second region 22. Moreover, the horizontal tube of the removal apparatus 25 projecting into the scull crucible 1 advantageously allows the melt to be removed from regions of the installation volume which are not affected by the scull layer forming at the edge. It is also possible for the melting-down volume to remain relatively large in the case of glasses where there are high demands on the internal homogeneity and extremely high demands on the transmission, but relatively low demands on the absence of bubbles. In addition, however, the refining volume also has to be selected to be significantly larger than in the case illustrated in FIG. 2a. A situation of this nature is shown in FIG. 2b. The variably positionable bridge 2 is arranged in such a manner in the scull crucible 1 that the melting-down volume is smaller and the refining volume larger compared to the arrangement shown in FIG. 2a. To illustrate a further example of an embodiment of the removal apparatus 25, FIG. 2b shows a simple bent-off tube. This is arranged within the turns of the radiofrequency coil 14.

In the case of optical glasses, high demands are imposed on the internal homogeneity and transmission of the glass, but also high demands are imposed on the absence of bubbles. In this case, the refining volume has to be selected to be as large as possible in order to ensure the absence of bubbles and a high degree of homogeneity.

A solution to these requirements is illustrated in the arrangement shown in FIG. 2c. The variably positionable bridge 2 is now arranged in such a way that the volume of the first region 12, the melting region, has been reduced in favor of the volume of the second region 22, the refining region. In this case, the removal apparatus 25 has a stirring crucible for further homogenization of the glass prior to further processing.

The variable positioning of the bridge 2 and of the removal apparatus 25 allow the volume of the first region 12 and of the second region 22 of the scull crucible 1 to be adapted to the particular demands imposed on the product quality and the throughput, as has been demonstrated on the basis of the explanations given in connection with FIGS. 2a to 2c.

Furthermore, the invention offers the option, through the use of further devices, to temporally and locally flexibly influence the temperature and therefore the viscosity and flow of the crucible contents 30 in various ways. Devices of this type are illustrated in FIG. 3.

In particular, the apparatus according to the invention may be equipped with a stirrer, preferably with a water-cooled stirrer, 52. In particular in the first region 12, the melting region, it is possible to use the stirrer 52 to uniformly distribute the added batch in the crucible contents 30. In particular by virtue of the batch which is added from above being quickly drawn under the surface of the crucible contents 30 with the aid of the stirrer 52, the batch is quickly delivered into the region which is heated by the energy introduced by the radiofrequency coil 14. In this way, the use of a stirrer 52 has beneficial effects on the melting capacity.

Forced convection to ensure intimate mixing of the crucible contents 30 in the first region 12 and/or the second region 22 of the scull crucible 1 can also be achieved by the introduction of gas bubbles (bubbling). To enable bubbling of this nature to be carried out, it is possible, for example, to employ a bubbling tube which is inserted from above, or, as shown in FIG. 3, a nozzle 32, 35 positioned, for example, in the base. The refining process is also enhanced by the gas bubbles introduced into the crucible contents 30.

In particular, when the installation is being started up, it may be useful for it to be possible to heat the batch in addition to and independently of the energy introduced via the radiofrequency coil 14. This may be realized, for example, with the aid of a burner 42, 45 in the feed region 10 and/or in the discharge region 20. The burners 42, 45 can be switched on during ongoing operation in order, for example, to increase the melting-down capacity or to assist the temperature control.

FIG. 4 shows an enlarged view of the excerpt indicated by XX from the apparatus illustrated in FIG. 1. In this example, the variably positionable removal apparatus 25 is arranged beneath the radiofrequency coil 14. The removal apparatus 25 is guided through an opening in the wall of the scull crucible 1. There is a short-circuiting ring 23 which prevents electrical sparkovers between the tubes of the scull crucible 1 located in this opening. The removal apparatus 25 is connected to the short-circuiting ring 23 via the conductive connection 18, in order to prevent electrical sparkovers between the removal apparatus 25 and the tubes of the scull crucible 1.

Depending on the type of glass and thickness of the scull crust 11, the removal apparatus 25 projects into the interior of the scull crucible 1. The removal apparatus 25 is therefore also in addition heated indirectly by the surrounding melt of the crucible contents 30.

In the example shown, the removal apparatus 25 is of double-walled design, so that, by way of example, liquid cooling can be realized in the interior of the removal apparatus 25. The coolant is fed to the double-walled removal apparatus 25 through the feed connection piece 21 and removed again via the discharge connection piece 27.

Feed connection piece 21 and discharge connection piece 27 are illustrated opposite one another in FIG. 4. This arrangement is not imperative; by way of example, the discharge connection piece may also be arranged on that side of the removal apparatus 25 which is remote from the feed connection piece. In this way, it is then possible to realize a controlled countercurrent for cooling the removal apparatus.

### MELTING EXAMPLE

The example considers fiber-optic zinc silicate glasses with a composition range of
SiO₂ in a concentration of from 43 to 46% by weight,
ZnO in a concentration of from 33 to 38% by weight,
R₂O in a concentration of between 12 and 20% by weight, where
R₂O denotes alkali metal oxides,
and PbO in a concentration of between 0 and 4% by weight.

Extremely high demands are imposed on these fiber-optic zinc silicate glasses with regard to the purity and optical transmission. In this context, the absence of platinum and the minimization of polyvalent ions with a coloring effect are particularly important.

The fiber-optic zinc silicate glasses were melted in an apparatus according to the invention for melting inorganic substances. The volume of the scull crucible was 65 liters. The removal apparatus 25 was arranged laterally. The take-off was in this case located above the radiofrequency coil 14 and was double-walled and coolable in design.

The cooling media used were air and water-humidified air. The glasses were melted at frequencies of from 409 to 415 kHz and generator powers of from 120 to 225 kW. Burners 42, 45 were used from time to time to improve the melting-down capacity and the rate at which bubbles rise up in the upper part of the refining region 22.

Bubbling with the aid of oxygen was employed to improve the mixing in the melting region 12. The melting capacity of the apparatus was 0.6 to 0.7 tonne of glass per day. Various positions of the variably positionable bridge 2 were used and were found to have considerable effects on the temperature and the flow characteristics. Table 1 shows a summary of the test results.

TABLE 1
Temperature gradient ΔT between melting region
and refining region as a function of the bridge
position

| | | | Through- | ΔT (K) |
|---|---|---|---|---|
| | Melting | Refining | flow | melting |
| Bridge | volume | volume | height/total | region/refining |
| position | (L) | (L) | height | region |
| A | 32.5 | 32.5 | 2/3 | 80 |
| B | 22.0 | 43.0 | 2/3 | 30 |
| C | 43.0 | 22.0 | 2/3 | 50 |
| D | 43.0 | 22.0 | 1/2 | −50 |
| E | 32.5 | 32.5 | 1/2 | 120 |

With a constant ratio of melting volume in region 12 to refining volume in region 22, it is possible to produce a considerable temperature difference AT between the temperature of the region 12 used for melting and the temperature of the region 22 used for refining by changing the ratio of the through-flow height to the overall height, i.e. by altering the vertical position of the bridge 2.

Even with a bottom outlet instead of the lateral outlet described above, it is possible to achieve a temperature difference ΔT of 120K as in example E. The other parameters likewise take the values given above. The bottom outlet in this case projected 150 mm into the scull crucible and was air-cooled and water-cooled.

1. A process for melting inorganic substances in a scull crucible having a feed side and a discharge side, the process comprising:
setting a first volume of a first region on the feed side of the scull crucible and/or a second volume of a second region on the discharge side of the scull crucible;
adding a batch into the first region;
melting down the batch;
moving a portion of the batch into the second region;
melting down and/or refining the portion in the second region; and
removing the melted-down and/or refined portion through a removal apparatus.

2. The process as claimed in claim 1, wherein the first volume and/or the second volume is set by variable positioning of at least one bridge.

3. The process as claimed in claim 2, wherein the variable positioning of the at least one bridge sets a flow of the batch.

4. The process as claimed in claim 3, further comprising positioning the at least one bridge to set the flow in an area selected from the group consisting of the first region, from the first region into the second region, in the second region, and from the second region into the removal apparatus.

5. The process as claimed in claim 2, further comprising positioning the at least one bridge horizontally and/or vertically in the first region and/or the second region.

6. The process as claimed in claim 5, of further comprising positioning the at least one bridge during a starting-up operation.

7. The process as claimed in claim 6, further comprising altering the position of the at least one bridge while the process is being carried out.

8. The process as claimed in claim 5, further comprising controlling the position of the at least one bridge while the process is being carried out.

9. The process as claimed in claim 5, wherein the position of the at least one bridge is set as a function of the viscosity of the batch.

10. The process as claimed in claim 2, further comprising cooling the at least one bridge.

11. The process as claimed in claim 2, further comprising setting a temperature difference between the contents of the first region and the second region by varying the positioning of the at least one bridge.

12. The process as claimed in claim 1, wherein the second volume is set by variable positioning of the at least one removal apparatus.

13. The process as claimed in claim 12, further comprising heating and/or refining the melted-down and/or refined portion during the removal of the melted-down and/or refined portion.

14. The process as claimed in claim 13, wherein the heating and/or refining during the removal is carried out by direct electrical heating.

15. The process as claimed in claim 1, further comprising cooling the melted-down and/or refined portion during the removal the melted-down and/or refined portion.

16. The process as claimed in claim 15, wherein the cooling comprises gas cooling, aerosol cooling, liquid cooling, and any combinations thereof.

17. (canceled)

18. The process as claimed in claim 1, wherein melting down and/or refining the portion comprises radiofrequency heating.

19. The process as claimed in claim 1, further comprising cooling the scull crucible.

20. The process as claimed in claim 1, further comprising imparting forced convection to the flow of the batch on the feed side and/or the discharge side.

21. The process as claimed in claim 20, wherein the forced convection is imparted by stirring and/or bubbling.

22. The process as claimed in claim 13, further comprising a third heating and/or refining step.

23. The process as claimed in claim 22, wherein said third heating and/or refining step comprises surface heating of the batch.

24. The process as claimed in the claim 1, further comprising feeding the melted-down and/or refined portion for shaping.

25. An apparatus for melting inorganic substances, comprising:
a scull crucible having a feed side with at least one first region and a discharge side with at least one second region;
a device for adding a batch into the at least one first region;
a device for heating the batch;
a removal apparatus for removing the batch from the at least one second region; and
at least one device for variably setting the volume on the feed side and/or the discharge side of the scull crucible.

26. The apparatus as claimed in claim 25, wherein the at least one device comprises at least one variably positionable bridge.

27. The apparatus as claimed in claim 26, wherein the scull crucible and/or the at least one variably positionable bridge comprises a metal, selected from the group consisting of steel, platinum, copper, aluminum, and alloys thereof.

28. The apparatus as claimed in claim 26, wherein the at least one variably positionable bridge is slotted.

29. The apparatus as claimed in claim 27, wherein the metal further comprises a coating.

30. The apparatus as claimed in claim 26, further comprising a device for the horizontal and/or vertical positioning of the at least one variably positionable bridge.

31. The apparatus as claimed in claim 26, further comprising a device for changing the position of the at least one variably positionable bridge while the process is being carried out.

32. The apparatus as claimed in claim 31, further comprising a device for controlling the position of the at least one variably positionable bridge.

33. The apparatus as claimed claim 26, further comprising a device for cooling the at least one variably positionable bridge.

34. The apparatus as claimed in claim 25, wherein the removal apparatus is positionable on the discharge side projecting into the scull crucible.

35. The apparatus as claimed in claim 34, wherein the removal apparatus comprises a material selected from the group consisting of metal, ceramic, and glass.

36. The apparatus as claimed in claim 34, further comprising a device for heating the removal apparatus.

37. The apparatus as claimed in claim 34, further comprising device for cooling the removal apparatus.

38. The apparatus as claimed in claim 34, further comprising a device for short-circuiting the removal apparatus with the scull crucible.

39. (canceled)

40. The apparatus as claimed in claim 25, wherein the device for heating the batch has a radiofrequency coil which at least partially surrounds the scull crucible in the vertical direction.

41. The apparatus as claimed in claim 25, wherein the scull crucible is slotted.

42. The apparatus as claimed in claim 25, further comprising a device for short-circuiting the tubes which form the scull crucible.

43. The apparatus as claimed in claim 42, further comprising a device for cooling the scull crucible.

44. The apparatus as claimed in claim 25, further comprising at least one device for stirring the batch on the feed side and/or on the discharge side.

45. The apparatus as claimed in claim 25, further comprising at least one device for introducing bubbles into the batch on the feed side and/or on the discharge side.

46. The apparatus as claimed in claim 25, further comprising at least one burner for heating the batch on the feed side and/or on the discharge side.

47. The apparatus as claimed in claim 25, further comprising a device for homogenizing the batch.

48. The apparatus as claimed in claim 25, further comprising a device for passing on the batch.
